(19) United States
(12) Patent Application Publication
(10) Pub. No.: US 2017/0164670 A1
(43) Pub. Date: Jun. 15, 2017

(54) DATA SECURITY POCKET AND GARMENT

(71) Applicant: Stanley Hale, Jellico, TN (US)

(72) Inventor: Stanley Hale, Jellico, TN (US)

(21) Appl. No.: 15/379,423

(22) Filed: Dec. 14, 2016

Related U.S. Application Data
(60) Provisional application No. 62/267,880, filed on Dec. 15, 2015.

(51) Int. Cl. A41D 27/20; A41D 31/02; H05K 9/00; A41D 27/24

(52) U.S. Cl. CPC A41D 27/205; A41D 27/24; A41D 27/201; A41D 31/02; H05K 9/0081

(57) ABSTRACT

A data security pocket and garment is disclosed for better positioning and protecting data and information contained in a card or device for housing such information from its theft or misappropriation when it is placed in the pocket portion of the invention. The pocket portion of the invention is specially positioned on and secured to a portion of the garment or clothing surface near or adjacent to the arm-pit area with which it is used in combination, with its own design, to provide a more protective pocket environment for placement and transportation of a card, chip or other data/information carrying or storing device or means. The pocket and the garment in combination make up four layers from which the pocket is constructed, secured and positioned. These layers include the top pocket layer (12); the top security layer (14) and the bottom security layer (16), each fabricated from security anti-RFID material; and the garment, clothing or base layer (18). These layers are connected one to the other so that the pocket portion has a first accessible opening (40) and a second accessible opening (42) when secured in proper position on the garment (18). Further provided is the trim security flap cover (22), also fabricated from security anti-RFID material, and the upper cover enclosure (20), each of which is secured above the pocket portion on the garment layer (18), and which pivot and close over the top pocket layer (12). Coupling is provided for both the upper cover enclosure (20) and the top pocket layer (12); and the trim security flap cover (22) and the top pocket layer (12). In another aspect of the invention an auxiliary security area (39) is provided on the top pocket layer (12) adjacent or near the coupling for the trim security flap (22).

### CROSS-REFERENCE TO RELATED APPLICATIONS

This application claims the benefit of U.S. Provisional Application Ser. No. 62267880, filed Dec. 15, 2015, the disclosure of which is incorporated by reference as if copied verbatim in its complete entirety.

### BACKGROUND OF THE INVENTION

1. Field of the Invention

The present invention relates to a garment with security pocket and to a garment with such a pocket construction specially positioned when utilized with a garment, where the pocket is structured to provide increased security against the theft or improper dissemination or uploading of data housed in a device placed for such protection into the pocket of the invention.

2. Background Information

For the last number of years various types of data protection garments and/or pockets have been designed to protect against undesired theft or transfer of information and data stored or housed in a computer-like or software device, or other electric storing device for data and information such as, but not limited to, credit cards and other storage devices having a chip, micro-chip or other data/information storage elements or means. Some of these pocket-type data protective devices were at least partially helpful in preventing against the theft of information or data. Other inventions described and set fort in past technology appeared to be less effective or user-friendly to the person wearing the garment or utilizing a protective pocket for such purposes.

Some of the inventions in the past technology striving to prevent the theft of data and information from a device carried or transported by the user, or seeking to protect the user, themselves, from electro-magnetic exposure (a generally related, but specifically different function) have included the following references:

WO2005044030A1 (where a side regional location is disclosed for the purpose of better securing a cell phone device; but where no disclosure is made regarding the protecting of, the safety of electrical data contained in a device).

U.S.D574,608S1 (a Design Patent Reference showing a visual disclosure of regionally located, side-positioning without visual disclosure pertaining to protection of electrical or computerized data).

U.S.20020157170A1 disclosing a side positional location for a security pocket; but disclosing and claiming “A security pocket assembly for retaining articles”, not such a pocket for protecting the theft of data contained in computer or electrical devices).

U.S.2013239298A1 (disclosing a side pocket positional orientation, but again making no provision for the protection of electrical data).

U.S.2011307991A1 (disclosing “a torso-covering garment having a laterally-accessible pocket for holding a cellphone or the like”. Again, there is no function disclosed for protecting theft or misappropriation of electrical or stored data).

U.S.2005193460A1 (side position of a pocket-like structure, but only for the purpose of storing long sleeves for the garment inside this for the purpose of installing them if desired).

U.S. Pat. No. 3,688,315 (a possible side position disclosed in at least one of its embodiments in terms of a hidden pocket in positional relation to an already constructed first pocket; but which yet again makes no provision for the protection of electrical data).

FR2793116A1_F (a French patent Reference, where side-positioned pocket elements for holding cell phones and even a credit card are disclosed; but with no function disclosed for protecting the storage data of or within such an object or device).

Side POCKET_1F (Internet Reference) (this first photograph taken off the internet shows a side-positioned blazer pocket which has the function of protecting against data theft; see: https://www.betabrand.com/womens-rfid-blocking-pocket-norton-black-blazer.html).

Side POCKET_2 (Internet Reference) (shows a further internet reference where a separate side-positioned shoulder-holster-type construction is shown which is said to have RFID and frequency blocking ability; and, therefore provide protection from theft of electronic data information on credit cards and such; but which is not part of the shirt or blazer garment itself) (see: http://www.corporatetravelsafety.com/safety-tips/category/pickpockets/tip/common-pickpocket-techniques).

Side Pocket_3 (Internet Reference) (this further internet reference shows a side-positioned pocket which is designed to store thin items like credit cards and such; but which discloses no function in protecting the theft of data stored within or associated with these items) (See: http://www.latimes.com/travel/deals/la-trb-gear-undershirts-with-hidden-pockets-20140320-story.html).

### SUMMARY OF THE INVENTION

The foregoing and other objects of the invention can be achieved with the present invention's DATA SECURITY POCKET, and the Data Security Pocket used in combination with a Garment, and it's device and system. In one aspect an object of the present invention is to provide a well-protected data security pocket which can be positioned under the area of the arm pit portion of the garment to provide strategic protection under the garment wearer's arm when the garment is worn by the wearer. An additional closely related object of the present invention is to provide the security pocket portion of the invention, itself, in the such an underarm location, while still providing at least two access locations into the interior of the pocket portion itself; thus allowing good access to the pocket portion, which is easily reached or accessible by the garment wearer, while taking advantage of the under-arm position to make it more difficult for a ‘would be’ data thief to position an RFID or other data theft device properly in relation to the data storage device being protected in the pocket to steal data information. Thus, objectives and advantages in the invention are provided for better concealing and protecting a data storage device, while allowing multiple accesses by the user or wearer of the garment into the protected pocket area itself.

### BRIEF DESCRIPTION OF THE DRAWINGS

FIG. 1 is a drawing illustration showing an upper view of the DATA SECURITY POCKET AND GARMENT of the present invention.

FIG. 2 is a drawing illustration showing an elevated view of the embodiment of FIG. 1, where the upper cover enclosure (20) is in a closed position.

FIG. 3 shows a partial drawing representation of the side of a shirt garment illustrating placement under the arm in the arm pit area of the garment, of the embodiment of FIG. 1 of the present invention.

FIG. 4A is a drawing photographic illustration of a garment portion used in combination with the pocket of the present invention, and placement of the embodiment of FIG. 1 under the right arm-pit area of the garment, as preferred in one aspect of the invention, in placement of the embodiment of FIG. 1.

FIG. 4B is a drawing-photographic illustration of a typical garment used with the present invention, and placement of the embodiment of FIG. 1 under the left arm-pit area of the garment, as preferred in one exemplar aspect in placement of the embodiment of FIG. 1.

FIG. 5 is an elevated perspective view, sketch-photo illustration of another preferred embodiment of the DATA SECURITY POCKET AND GARMENT of the present invention.

FIG. 6 is a side perspective view, sketch-photo illustration of the embodiment of FIG. 5.

FIG. 7 is a front elevated view, sketch-photo illustration of the embodiment of FIG. 5.

FIG. 8 is a side perspective view, sketch-photo illustration of the embodiment of FIG. 5, showing the two access areas to the pocket of the invention.

FIG. 9 is a front elevated perspective view, sketch-photo illustration of the embodiment of FIG. 5.

FIG. 10 is a further side perspective view, sketch-photo illustration of the embodiment of FIG. 5.

FIG. 11 is an elevated view of the pocket and garment of the present invention showing placement of the embodiment of FIG. 5 of the invention in the arm pit area (37).

FIG. 12 is a side perspective view, sketch-photo illustration of the another embodiment of the invention.

FIG. 13 is a side perspective drawing sketch-photo illustration of the embodiment of FIG. 5.

FIG. 14 is an elevated front view drawing illustration of a portion of another embodiment of the present invention.

FIG. 15 is an elevated front view drawing illustration of portions of the embodiment of FIG. 14.

FIG. 16 is a further elevated front view drawing illustration of the embodiment of FIG. 14.

FIG. 17 is a further elevated front view drawing illustration of the embodiment of FIG. 14.

### REFERENCE NUMBERS USED IN THE APPLICATION

10 Data security pocket and garment of the invention
12 top pocket layer
14 upper security layer
16 bottom security layer
18 Garment or separate support base layer or fourth layer
18A outside garment surfacing of (18)
18B inside garment surfacing of (18)
20 upper cover enclosure
20i inside layer (21i) of the upper enclosure (20)
21 L-seam
21A left or side section of (21)
21B bottom section of (21)
22 Trim security flap cover
24 first self retaining coupling
25 upper seam securing top pocket layer (12) and upper security layer (14)
26 second self retaining coupling
27 side seam securing top pocket layer and underneath adjacent portion of upper security layer (14)
28 inner side seam
29 Quarter corner security seam or attachment means (securing the layers)
31 cover seam support
33 first reciprocating coupling member of (22)
35 second reciprocating coupling member of (12)
37 Side view of garment under arm area, or arm-pit area of a garment used in combination with the pocket of the invention.
39 auxiliary security patch, area or element
40 first accessible or accessible side portion opening of the pocket (10)
42 second accessible or accessible top portion opening of the pocket (10)

### DETAILED DESCRIPTION OF PREFERRED EMBODIMENTS OF THE INVENTION

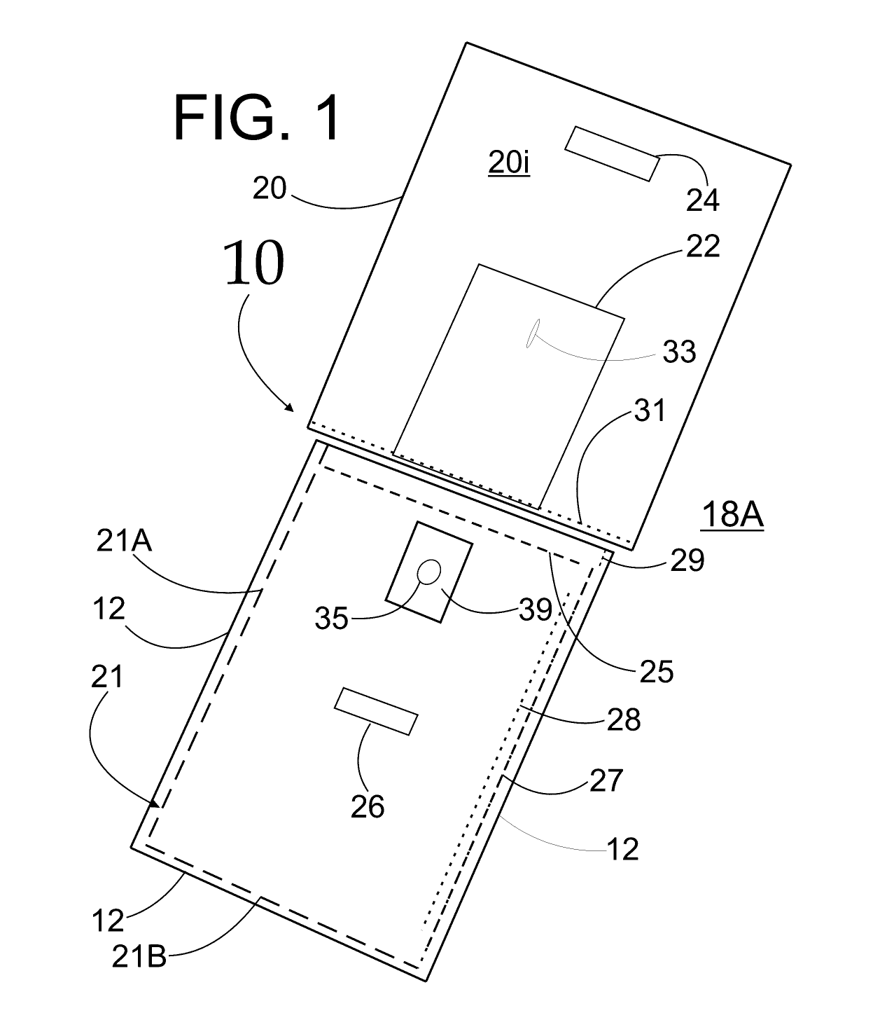

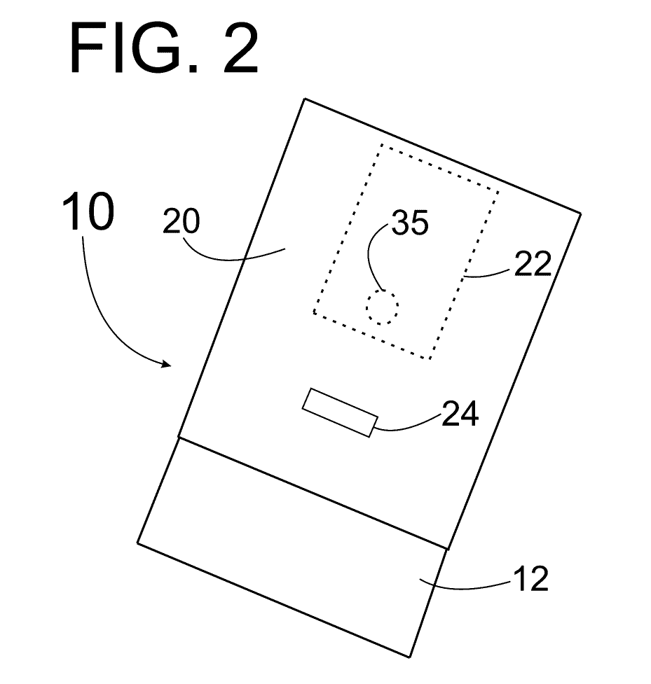

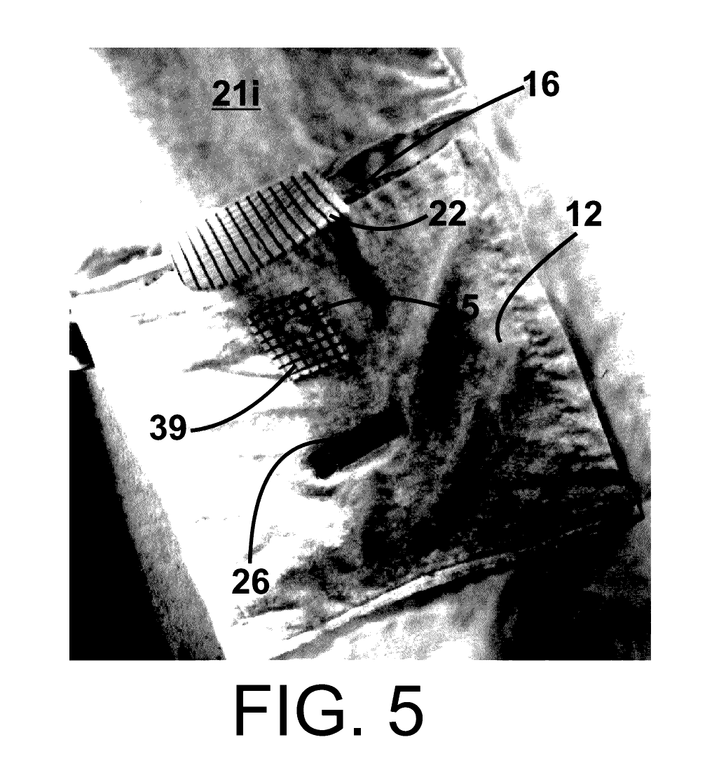

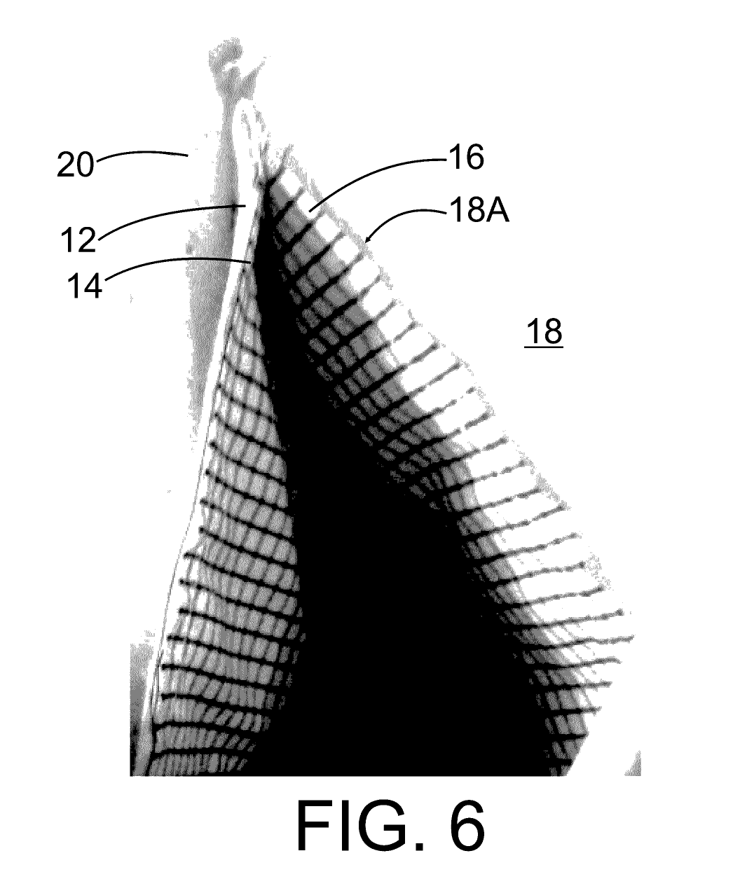

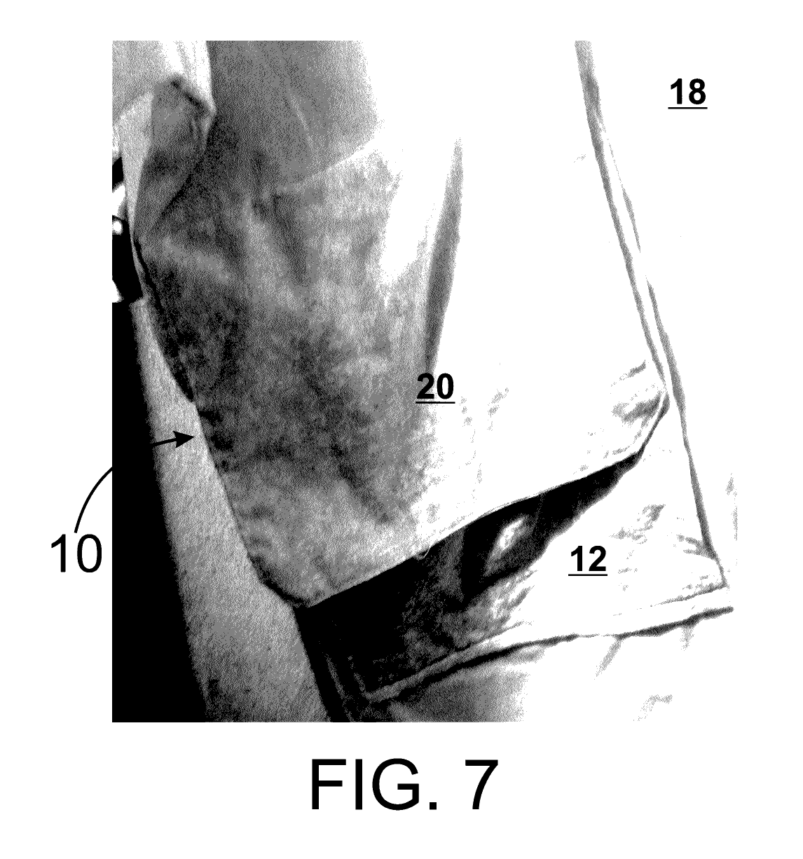

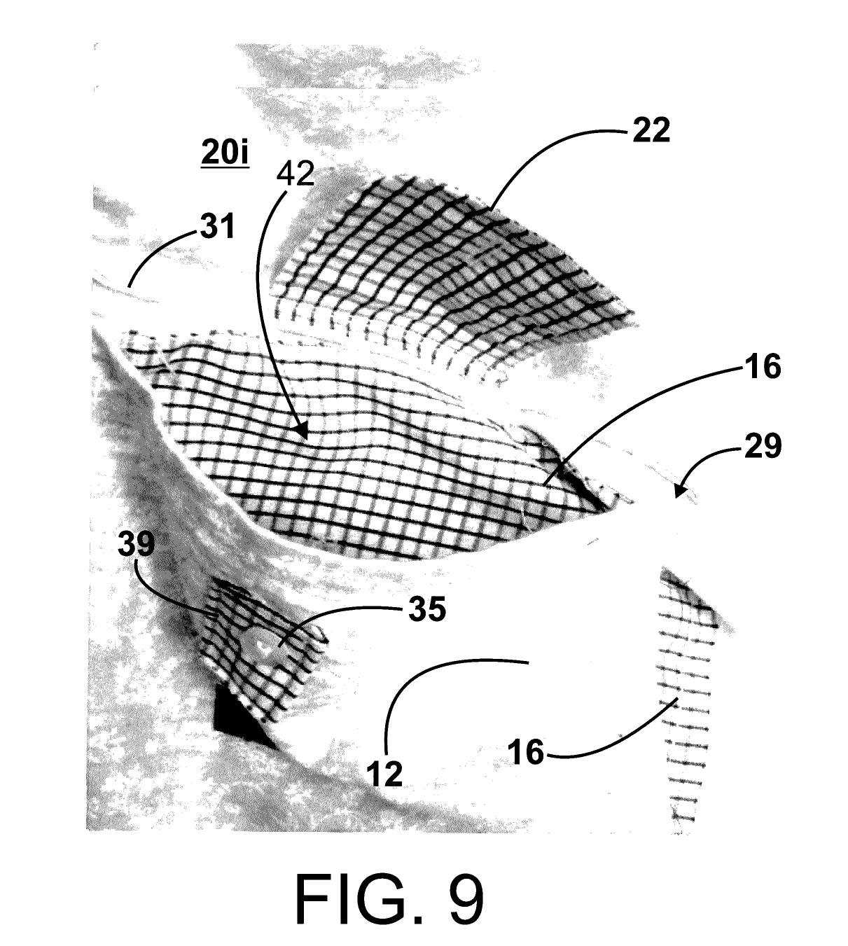

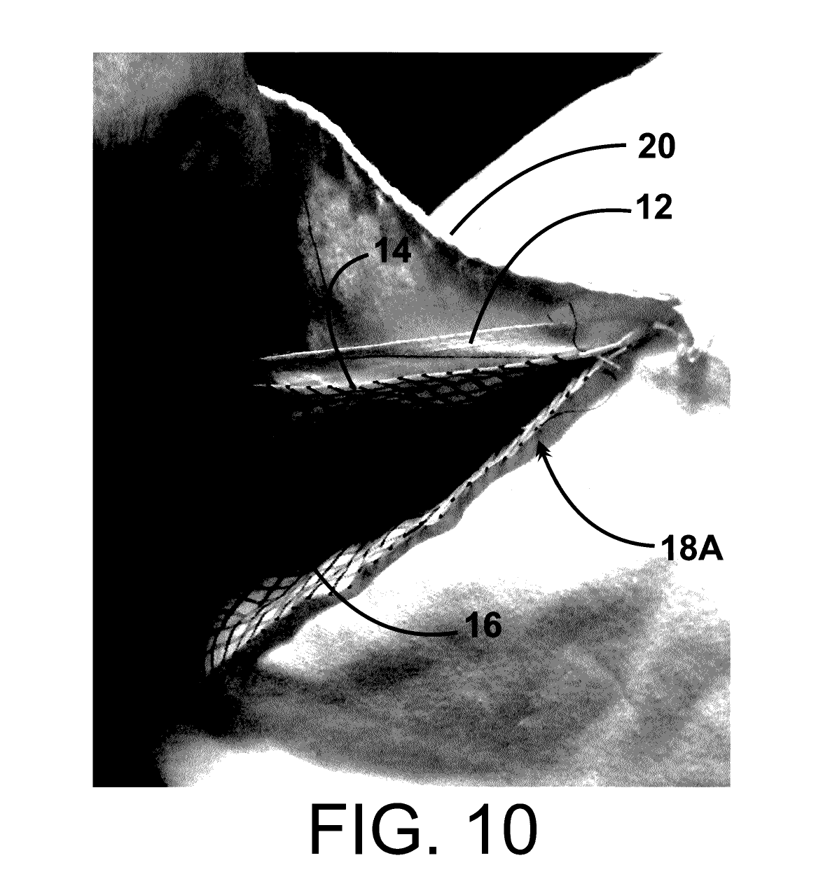

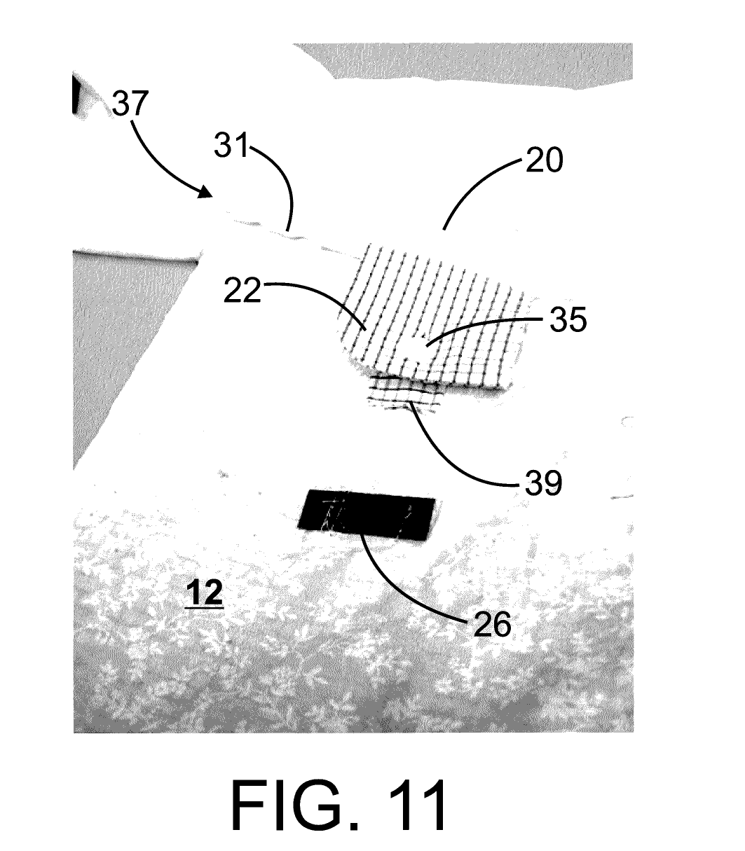

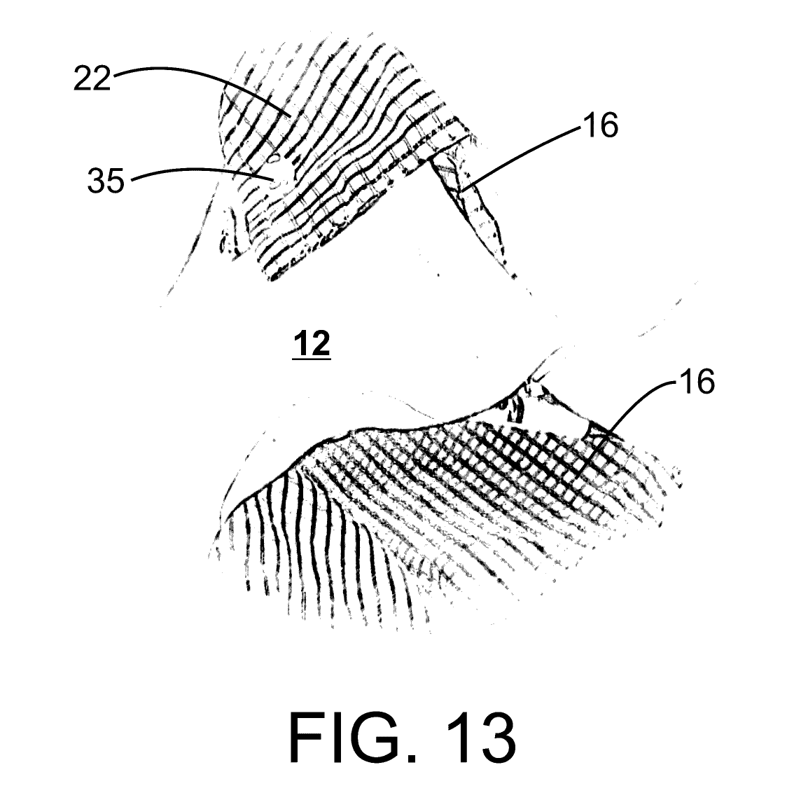

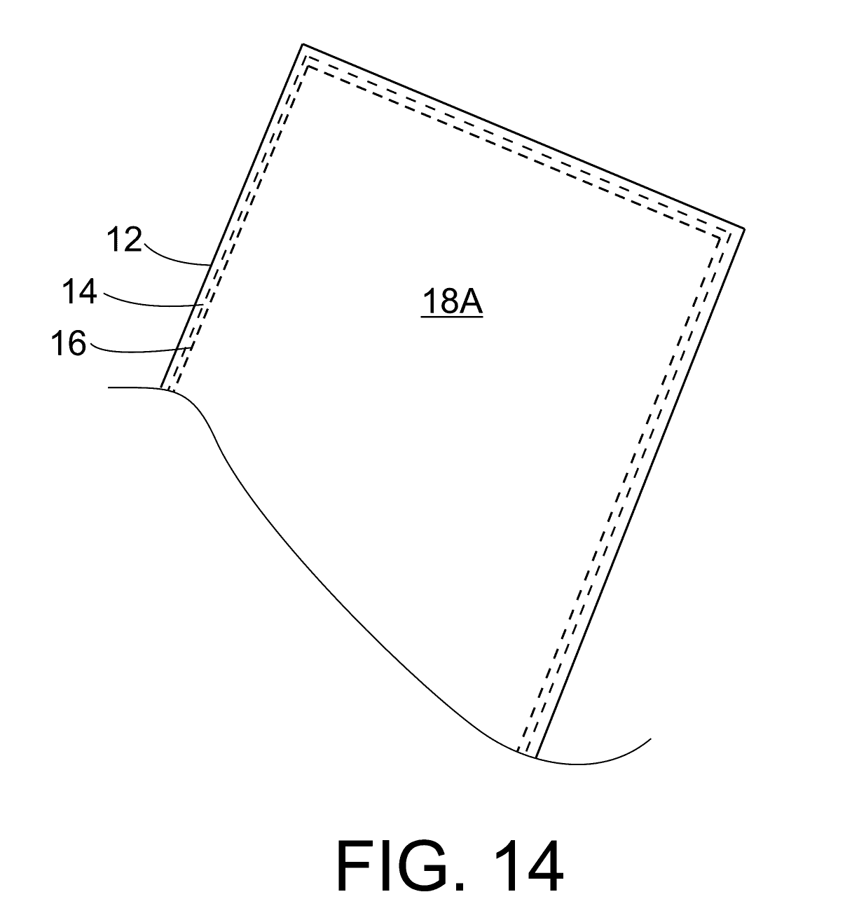

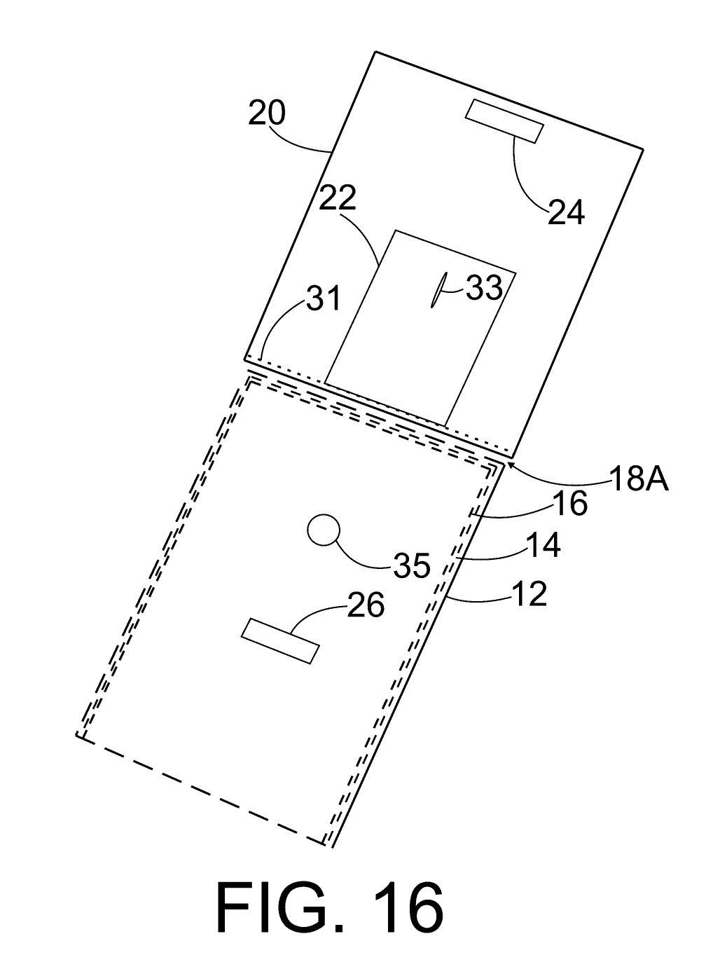

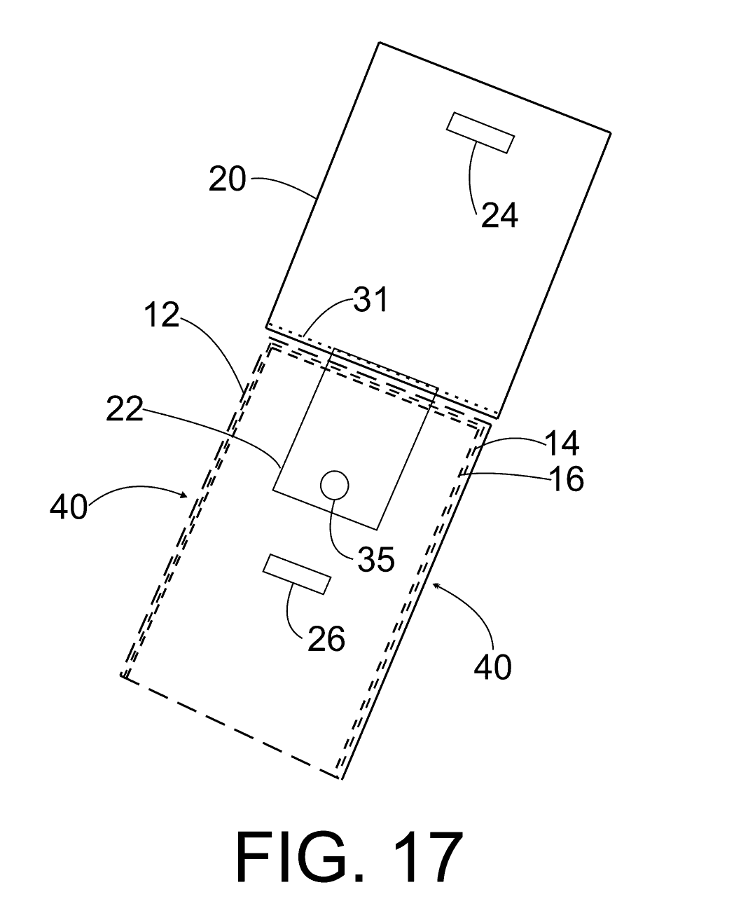

In a preferred embodiment, as illustrated by example in FIGS. 1 through 17, the Data Security Pocket and Garment of the invention 10 (security pocket) in its attached relationship to the clothing garment is basically composed and fabricated of the top pocket layer (12), the upper security layer (14), the bottom security layer (16) and the outside garment layer or surfacing (18A) of the garment (18). The garment layer or surfacing (18A) can also be a another or non-garment surfacing with which the pocket portion of the invention is used in combination for attachment thereto, which can, then itself be positioned and attached or secured to another surfacing.

The L-seam (21), as illustrated by example in FIG. 1, secures, at its left or side section (21A) the top pocket layer (12), the upper security layer (14) and the outside garment surfacing (18A); and at its bottom section (21B) the layers (12), (14), (16) and (18A). The upper seam (25) secures the top pocket layer (12) and the upper security layer (14). The three layers of the security pocket of the present invention 10; (12), (14) and (16), in additional preferred embodiments of the invention; are also bound and secured together on the outside garment layer or surfacing (18A), so that at least one vertical side and the top lateral or substantially perpendicular side of the layers constituting the pocket can be bound to the outside garment surfacing (18A). This allows a vertical side of the pocket to be open for entry along with the top side of the pocket or pocket layers. Or, as shown in the Drawing Figures, three sides of the layered pocket are secured to the outside garment surfacing (18A). It is indicated by description herein, and it will also be understood within the scope and spirit of the invention (10, that what is described herein as the outside garment surfacing (18A) of the garment layer (18) can be a separate individual layer apart from that of a garment, which acts as the bottom support surfacing of the pocket itself, when the pocket portion of the invention (10) is not mounted directly in combination with a garment; which can, itself be secured or installed on either a non-garment surface or a garment surface.

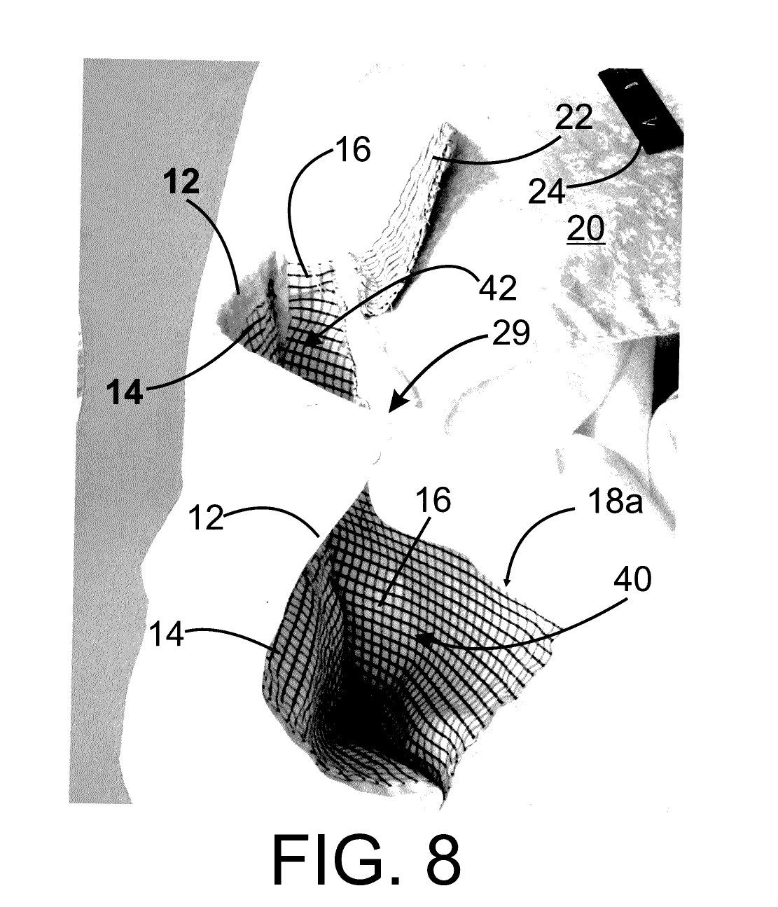

As indicated, the upper seam 25 secures the top pocket layer (12) and the upper security layer (14). The side seam 27 secures the top pocket layer 12 and the underneath adjacent portion of the upper security layer (14). The Quarter corner security seam 29 secures the layers (12), (14), (16) and (18A). In so doing, the first or side accessible pocket opening 40 is created and supported on one side of the seam 29, and the second or top accessible pocket opening 42 is created on the other side of the seam 29, as illustrated by example in FIGS. 8, 9, and 13. This provides two access portions into the security pocket created between layers 12 and 14, while still allowing the upper cover enclosure 20 and the trim security flap cover 22 to close over the top pocket layer 12. The trim security flap cover 22 is fabricated from or surfaced with the same security materials (or similar such material) utilized to construct or fabricate the upper security layer (14) and the bottom security layer (16), utilized in the present invention 10. The cover seam support 31 secures both the trim security flap 22 and the upper cover enclosure 20 to the outside garment surfacing (18A), or to a separate surfacing apart from a garment itself acting as a base support, which can, itself be secured to a garment or other surface. The trim security flap 22 is provided with the first and second reciprocating coupling members 33 and 35. The inside layer 20i of the upper cover enclosure 20 is further provided with the first self retaining coupling 24; and the top pocket layer 12 is provided with the second self retaining coupling 26 in a dimensionally spaced portion to the first self retaining coupling 24 of the inside layer 21i of the upper pocket 12 so that the first self retaining coupling 24 can be brought across and coupled with the second self retaining coupling 26 to close the upper enclosure 20 over the top pocket layer 12.

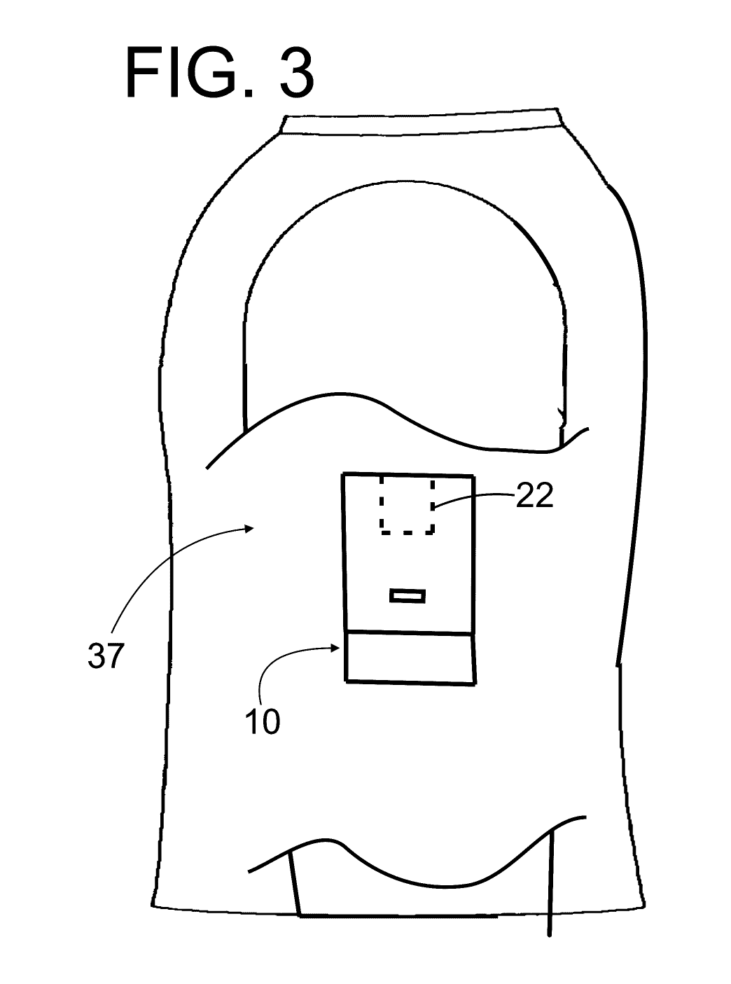

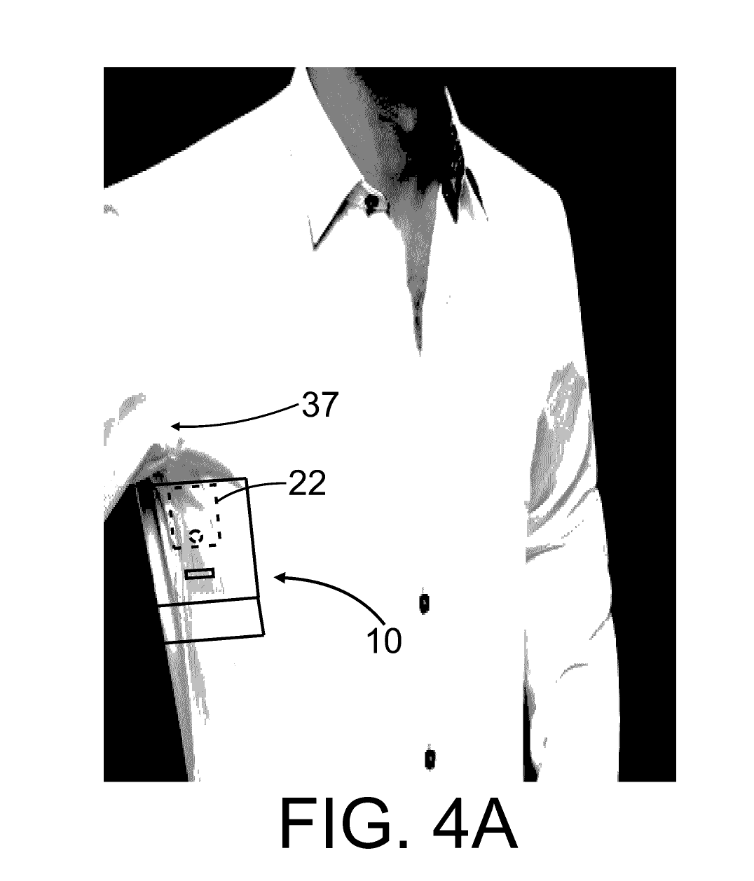

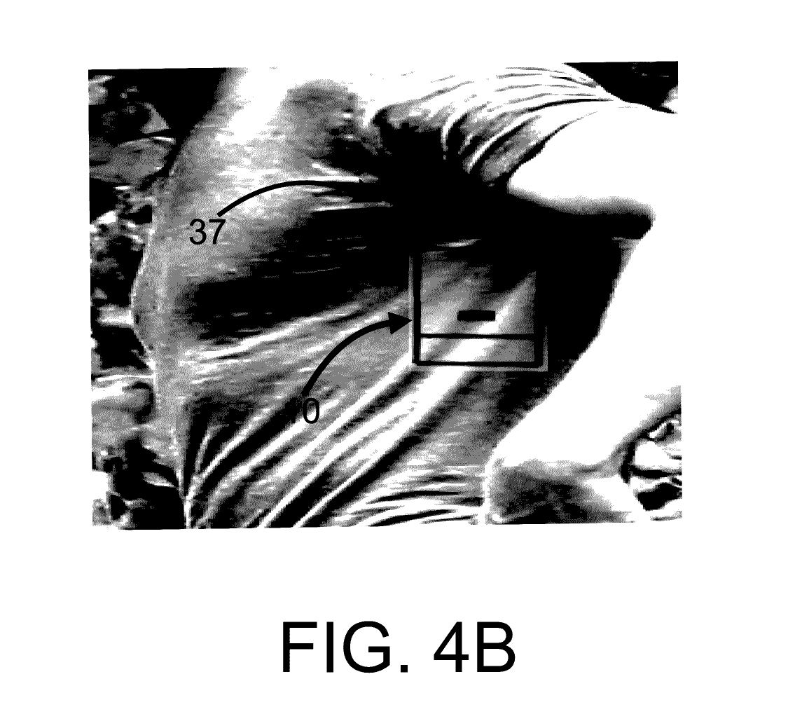

As shown in FIGS. 3, 4A and 4B, the security pocket of the present invention 10 is preferably positioned under the arm-pit area 37 of the garment to which it is attached. In this preferred embodiment the security pocket 10 can be positioned on the attaching garment under either, or both, of the two arm-pit arras (left or right arm or arm-pit areas) located on a standard or customized garment.

The inboard lining envelope or pocket, as contained within the upper security layer (14) and the bottom security layer (16), as well as constructive materials of the Trim security flap cover 22 and auxiliary security patch 39, are fabricated from a number of RFID, electromagnetic and signal blocking materials and fabrics, and EMF radio-wave/microwave shielding, and other materials or fabrics serving a ‘Faraday Cage’ functionality; including by example, but not limited to all of the following:

HertzCloth™ |High Conductivity & All Natural Shielding Fabric (see other related examples, herein);

### OurSure™ Conductive Fabrics;

### ArgenMesh™ Conductive/Shielding Silver

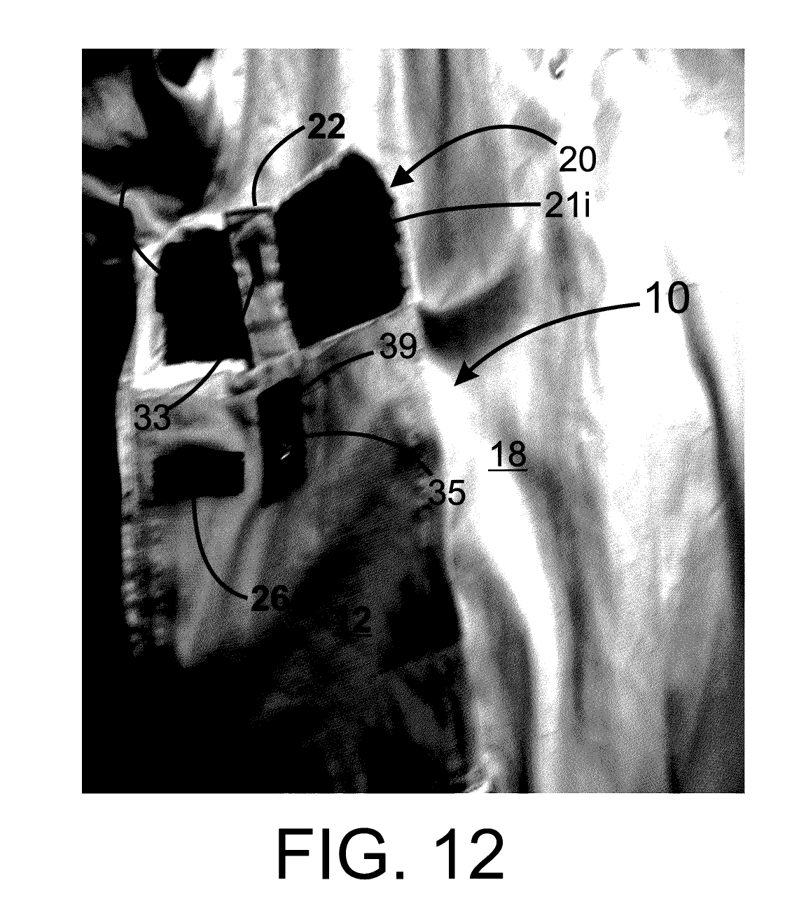

Shielding Fabric with Natural Look & Feel, for example, without limitation:
ArgenMesh
Evolution Ultra
Ex-Static
Safety Silk
Silver Jersey Knit
Silverell
Soft&Safe
Staticot
Stretch
   Cotton Based Shielding Fabrics, for example, without limitation:
Cotton Grid
HertzCloth
Naturell
SaniSilver™
Technicot
Wear
   Mesh-Type Shielding Fabrics, for example, without limitation:
Canopy Mesh
Daylite
ESD Static Fabric
High Performance Mesh
Stainless Steel Mesh
Copper Wire Mesh
VeilShield
   High Tech & Industrial Conductive Fabrics, for example, without limitation:
CobalTex
Nickel Copper Ripstop
Pure Copper Taffeta
RadioScreen
RipStop Silver
Shieldit Super
Stick E Shield™
   Other Fabric-like Shielding Materials, for example, without limitation:
AL60
Conductive Fabric Tape
Conductive Thread
Copper Wire Mesh
Hook & Loop
Microwave Absorber
Mesh Conductive/Shielding Silver Fabric
Woven, or meshed, or intersticed, RFID/RF Blocking Fabric, Material or Substance
Other Shielding, Blocking and/or Conducting Fabrics or Mesh Fabrics
   Many of the metal, metal alloy and garment fabric fiber combinations or meshed, flexible, interwoven materials serve as good fabricating, RF blocking material for the inboard lining envelope or pocket in preferred embodiments of the present invention, and more particularly in the present invention for the upper security layer (14), the bottom security layer (16), portions of the Trim security flap cover (22) and the area around or adjacent to the second reciprocating coupling member (35); as well as, in related preferred embodiments, the inside layer (21i) of the upper enclosure (20), as shown by example in FIG. 12.

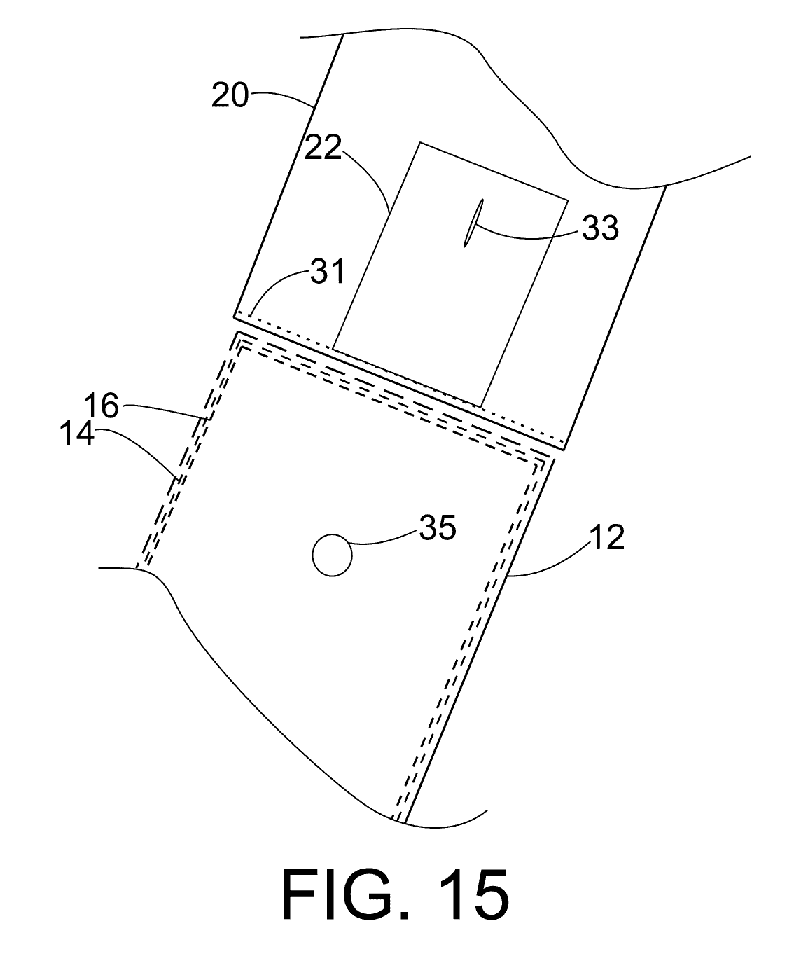

Further preferred embodiments of the present invention are illustrated by example in FIGS. 15 through 18. Illustrated in these embodiments of the present invention are aspects of the invention relating to the stitching and attaching of the elements (12), (14), (16) and (18A). Showing that each individual layer can be secured in relation to the pocket created or fabricated by their construction between layers 14 and 16. Layers 12, 14, 16 and 18A or 18 are secured to one another in preferred embodiments while permitting accessible entry into one or the other of the side portions 40 of the pocket 10, and the top portion 42 of the pocket.

It has been found in working with the present invention (10) that several RFID blocking fabric radio frequency shielding fabrics fabricated and constructed from flexible, heterogeneous fabric materials have performed well in the parts and portions of the pocket area where such materials have been employed as locationally described and discussed herein in their use and function in the invention. A particularly well suited fabric in this regard has been the RFID protection product involving stainless steel fiber woven into base fabric including polyester and cotton. This fabric is interwoven with about 28% Stainless Steele, 36% Cotton and 36% Polyester by weight. The blocking fabric encompasses Polyester/Cotton with micro fine stainless fibers, which creates a tough fabric similar to khaki. It provides, without limitation, grounding applications, electric field shielding, microwave shielding and RF shielding; and, importantly for objects and purposes of the invention, Faraday Cage Enclosure, thus, RFID signal blocking (to defeat electronic data theft). This fabric material thus functions well to effectively block RFID Radio frequency identification scanner signals. Importantly, the special spatial orientation and positioning of parts of the invention as set forth herein, as well as the positioning and installation of the pocket portion itself, as a whole, in relation to and combination with the garment portion of the invention, provides important and unique distinctions in relation to the prior art and technical field as a whole.

Other related useful, blocking fabric for fabricating the security portions of the pocket portion of the invention include, without limitation, an RFID Shielding cloth material having about 23% Copper, 27% Nickel and 50% Polyester.

While preferred embodiments of the present data security pocket and garment device invention 10 have been described and illustrated it will be appreciated by those skilled in the art that various changes can be made regarding the present invention without departing from the scope and spirit of this invention.

I claim:

1. A Data Security Pocket and Garment for carrying and protecting a device housing data; comprising first, second, third layers, and fourth base layer; respectively layers (12), (14), (16) and (18); the first layer (12) being a top pocket layer, the second layer (14) being an upper security layer, the third layer (16) being a bottom security layer, and the fourth layer (18) being a garment layer of the clothing with which the Data Security Pocket is used in combination; the layers (12), (14) and (16) being secured to one another and to the garment layer (18) such that a first accessible entrance and a second accessible entrance are defined between the upper security layer (14) and the bottom security layer (16); each of the security layers (14) and (16) being fabricated from materials serving to provide a Faraday Cage functionality with regard to any means seeking to steal data from the device housing data when carried in the Data Security Pocket and Garment; and
further comprising an upper cover enclosure (20) and, below that, a dimensionally smaller trim security flap cover (22), each of which is attached to the garment layer such that it can pivot, extend and close over portions of the top pocket layer (12).

2. The Data Security Pocket and Garment of claim 1, wherein, further comprising a first self retaining coupling (24), a second self retaining coupling (26), a first reciprocating coupling member (33) and a second reciprocating coupling member (35); the first self retaining coupling (24) being secured to the upper cover enclosure (20) and the second self retaining coupling (26) being secured to the top pocket layer (12) in a position relative to one another such that the retaining couplings (24) and (26) will engage one another when the upper cover enclosure (20) is positioned over the top pocket layer (12); the first reciprocating coupling (33) being defined by or secured to the trim security flap (22) and the second reciprocating coupling (35) being secured to the top pocket layer (12) in a position relative to one another such that the coupling members (33) and (35) will engage one another when the trim security flap (22) is pivoted and positioned over the top pocket layer (12).

3. The Data Security Pocket and Garment of claim 2, wherein, further comprising at least one auxiliary security portion adjacent or close to the second reciprocating coupling (35) on the top pocket layer (12).

4. The Data Security Pocket and Garment of claims 1; wherein, further comprising an L-seam (21), having a left or side section 21A which fixedly connects by sewn seam the top pocket layer (12), the upper security layer (14) and the garment layer (18); and a bottom section (21B) which fixedly connects and attaches by sewn seam the top pocket layer (12), the upper security layer (14), the bottom security layer (16) and the garment layer (18).

5. The Data Security Pocket and Garment of claims 2; wherein, further comprising an L-seam (21), having a left or side section 21A which fixedly connects by sewn seam the top pocket layer (12), the upper security layer (14) and the garment layer (18); and a bottom section (21B) which fixedly connects and attaches by sewn seam the top pocket layer (12), the upper security layer (14), the bottom security layer (16) and the garment layer (18).

6. The Data Security Pocket and Garment of claim 3; wherein, further comprising an L-seam (21), having a left or side section 21A which fixedly connects by sewn seam the top pocket layer (12), the upper security layer (14) and the garment layer (18); and a bottom section (21B) which fixedly connects and attaches by sewn seam the top pocket layer (12), the upper security layer (14), the bottom security layer (16) and the garment layer (18).

7. The Data Security Pocket and Garment of claims of claims 1; wherein, further comprising an upper seam (25) which fixedly connects and attaches by sewn seam the top pocket layer (12) and the upper security layer (14).

8. The Data Security Pocket and Garment of claims of claim 2; wherein, further comprising an upper seam (25) which fixedly connects and attaches by sewn seam the top pocket layer (12) and the upper security layer (14).

9. The Data Security Pocket and Garment of claim of claims 3; wherein, further comprising an upper seam (25) which fixedly connects and attaches by sewn seam the top pocket layer (12) and the upper security layer (14).

10. The Data Security Pocket and Garment of claims of claim 4; wherein, further comprising an upper seam (25) which fixedly connects and attaches by sewn seam the top pocket layer (12) and the upper security layer (14).

11. The Data Security Pocket and Garment of claim 7; wherein, an inner side seam (28) which fixedly connects and attaches the bottom security layer (16) and the garment layer (18).

12. The Data Security Pocket and Garment of claim 2; wherein further comprising a side seam (27) which fixedly connects and attaches the top pocket layer (12) and an adjacent portion of the upper security layer (14).

13. The Data Security Pocket and Garment of claim 1; wherein, further comprising a quarter corner security seam (29); said seam (29) being a short or single stitching or other securement means, attaching at that position the four layers (12), (14), (16) and (18).

14. The Data Security Pocket and Garment of claim 12; wherein, further comprising a quarter corner security seam (29); said seam (29) being a short or single stitching, attaching at that position only the four layers (12), (14), (16) and (18).

15. The Data Security Pocket and Garment of claim 1; wherein, the layers (12), (14), (16) and (18) are attached one to the other such that layers (12), (14) and (16) are secured to the garment layer so as to define or provide in attached position a first accessible side opening (40) and a second accessible top opening (42) between the upper security layer (14) and the bottom security layer (16), forming the internal chamber of the pocket.

16. A Data Security Pocket for carrying and protecting a device housing data; comprising first, second, third and fourth base layers, respectively layers (12), (14), (16) and (18); the first layer (12) being a top pocket layer, the second layer (14) being an upper security layer, the third layer (16) being a bottom security layer, and the fourth layer (18) being a support layer, which is suited to be, and can be attached to a clothing surface or other support surface with which the Data Security Pocket can be used in combination; the layers (12), (14) and (16) being secured to one another and to the support layer (18) such that a first accessible entrance and a second accessible entrance are defined between the upper security layer (14) and the bottom security layer (16); each of the security layers (14) and (16) being fabricated from materials serving to provide a Faraday Cage functionality with regard to any means seeking to steal data from the device housing data when carried in the Data Security Pocket;
an upper cover enclosure (20) and, below that, a dimensionally smaller trim security flap cover (22), each of which is attached to the support layer (18) such that it can pivot, extend and close over portions of the top pocket layer (12); and
wherein, the layers (12), (14), (16) and (18) are attached one to the other such that layers (12), (14) and (16) are secured to the support layer (18) so as to define or provide a first accessible side opening (40) and a second accessible top opening (42) between the upper security layer (14) and the bottom security layer (16), forming the internal chamber of the pocket.

17. The Data Security Pocket of claim 16, wherein, a first self retaining coupling (24), a second self retaining coupling (26), a first reciprocating coupling member (33) and a second reciprocating coupling member (35); the first self retaining coupling (24) being secured to the upper cover enclosure (20) and the second self retaining coupling (26) being secured to the top pocket layer (12) in a position relative to one another such that the retaining couplings (24) and (26) will engage one another when the upper cover enclosure (20) is positioned over the top pocket layer (12); the first reciprocating coupling (33) being defined by or secured to the trim security flap (22) and the second reciprocating coupling (35) being secured to the top pocket layer (12) in a position relative to one another such that the coupling members (33) and (35) will engage one another when the trim security flap (22) is pivoted and positioned over the top pocket layer (12).

18. Data Security Pocket for carrying and protecting a device housing data; comprising first, second, third and fourth layers, respectively layers (12), (14), (16) and (18); the first layer (12) being a top pocket layer, the second layer (14) being an upper security layer, the third layer (16) being a bottom security layer, and the fourth layer (18) being a support layer, which is suited to or suitable for being attached to an installation support surface with which the Data Security Pocket can be used in combination; the layers (12), (14) and (16) being secured to one another and to the support layer (18) such that a first accessible side entrance or opening (40) and a second accessible top entrance or opening (42) are defined between the upper security layer (14) and the bottom security layer (16); each of the security layers (14) and (16) being fabricated from materials serving to provide a Faraday Cage functionality, or frequency signal blocking function, with regard to any means seeking to steal data from the device housing data when carried in the Data Security Pocket;
an upper cover enclosure (20) and, below that, a dimensionally smaller trim security flap cover (22), each of which is attached to the support layer (18) such that it can pivot, extend and close over portions of the top pocket layer (12); and
a first self retaining coupling (24), a second self retaining coupling (26), a first reciprocating coupling member (33) and a second reciprocating coupling member (35); the first self retaining coupling (24) being secured to the upper cover enclosure (20) and the second self retaining coupling (26) being secured to the top pocket layer (12) in a position relative to one another such that the retaining couplings (24) and (26) will engage one another when the upper cover enclosure (20) is positioned over the top pocket layer (12); the first reciprocating coupling (33) being defined by or secured to the trim security flap (22) and the second reciprocating coupling (35) being secured to the top pocket layer (12) in a position relative to one another such that the coupling members (33) and (35) will engage one another when the trim security flap (22) is pivoted and positioned over the top pocket layer (12);
the layers (12), (14), (16) and (18) being attached one to the other such that layers (12), (14) and (16) are secured to the support layer so as to define or provide a the first accessible side opening (40) and the second accessible top opening (42) between the upper security layer (14) and the bottom security layer (16), forming the internal chamber of the pocket; and wherein a quarter corner security seam or attachment means (29) securing and defining an attachment boundary between the first accessible side opening (40) and the second accessible top opening (42).

19. The Data Security Pocket and Garment of claim 2, further comprising a cover seam support (31) for stitched or other securement or installed attachment of the upper cover enclosure (20) and the Trim security flap cover (22) to the fourth layer (18).

20. The Data Security Pocket of claim 17, further comprising a cover seam support (31) for stitched or other pivotable securement of the upper cover enclosure (20) and the dimensionally smaller trim security flap cover (22).
